(19) United States
(12) Patent Application Publication
(10) Pub. No.: US 2014/0238736 A1
(43) Pub. Date: Aug. 28, 2014

(54) Thermoplastic Resin Composition with EMI Shielding Properties

(71) Applicant: CHEIL INDUSTRIES INC., GUMI-SI (KR)

(72) Inventors: Kyoung Tae Youm, Uiwang-si (KR); Jee Kwon Park, Uiwang-si (KR); Young Sil Lee, Uiwang-si (KR)

(73) Assignee: CHEIL INDUSTRIES INC., GUMI-SI (KR)

(21) Appl. No.: 14/181,933

(22) Filed: Feb. 17, 2014

(30) Foreign Application Priority Data
Feb. 27, 2013 (KR) 10-2013-0020898
Feb. 11, 2014 (KR) 10-2014-0015201

(51) Int. Cl. H05K 9/00

(52) U.S. Cl. CPC H05K 9/009
USPC 174/388; 252/478

(57) ABSTRACT

A thermoplastic resin composition that can have excellent EMI shielding and injection-molding processability includes (A) a thermoplastic resin, (B) carbon fibers, and (C) filler comprising nano metal particles surface coated with graphite crystalline nano carbon particles, composite fillers which are carbon nanotubes coated with nano metal particles, composite fillers which are carbon nanotubes supporting nano metal particles, and combinations thereof.

### CROSS-REFERENCE TO RELATED APPLICATION

This application claims priority under 35 USC Section 119 to and the benefit of Korean Patent Application Nos. 10-2013-0020898, filed Feb. 27, 2013, and 10-2014-0015201, filed Feb. 11, 2014, the entire disclosure of which is incorporated herein by reference.

### FIELD OF THE INVENTION

The present invention relates to a thermoplastic resin composition that can have excellent electromagnetic interference (EMI) shielding properties.

### BACKGROUND OF THE INVENTION

With the development of multifunctional and miniaturized electrical/electronic products and information communication devices, the electromagnetic spectrum in use is changing to a higher frequency band, and thus electromagnetic pollution is steadily increasing in daily life. Specifically, electromagnetic radiation may result in malfunctions or failures of the surrounding devices, and may harm humans, e.g., causing a fever. As a result, there has been a growing demand for developing effective EMI shielding technologies which can prevent the aforementioned problems.

Conventional EMI shielding technologies directly process metal-based materials, or coat or plate metal-based materials to a substrate to form a conductive film. However, methods directly processing metal-based materials can exhibit poor processability when the end products have complex design, and also can result in increased weights. Further, coating the metal-based materials to form a conductive film requires many complicated process steps such as degreasing, etching, neutralizing, activating, metalizing, coating, etc., which can place a burden on productivity.

In contrast, electrically-conductive and EMI shielding materials using polymer composite resins may have advantages in terms of production costs and processability because the shielding materials can be produced by injection molding the composite resins.

EMI shielding efficiency (EMI shielding effectiveness) may be represented by the following formula:

Shielding Effectiveness(S.E.)=R+A+B

wherein R is surface reflection of electromagnetic waves, A is internal absorption of electromagnetic waves, and B is loss caused by multi-reflection.

Metallic materials have high EMI shielding effectiveness through the surface reflection of electromagnetic waves due to their high electrical conductivity (low impedance). Thus, in order to increase the EMI shielding effectiveness of a polymer composite resin, metallic fillers can be used to increase electrical conductivity and thereby increase surface reflection, and at the same time, fillers with high permeability can be used to increase the reflection of electric waves as well as the absorption of magnetic waves.

Korean Patent Publication No. 2011-0078265, which relates to a thermoplastic resin composition comprising a nanofiber-metal composite having improved permeability and conductivity, uses carbon fibers uniformly coated with metal to improve EMI shielding properties. However, as carbon fibers have large diameters and short lengths, the carbon fibers should be present in a high amount to maintain the targeted EMI shielding properties. In such a case, basic properties such as injection molding processability can be deteriorated.

### SUMMARY OF THE INVENTION

The present invention provides a thermoplastic resin composition that can have excellent EMI shielding properties and/or injection molding processability.

The thermoplastic resin composition of the present invention comprises (A) a thermoplastic resin, (B) a carbon fiber, and (C) fillers. Fillers (C) can include nano metal particles surface coated with graphite crystalline nano carbon particles, composite fillers which are carbon nanotubes coated with nano metal particles, and composite fillers which are carbon nanotubes supporting nano metal particles.

The thermoplastic resin composition of the present invention may comprise about 1 to about 8 parts by weight of the fillers (C) based on about 100 parts by weight of a base resin including about 50 to about 80% by weight of the thermoplastic resin (A) and about 20 to about 50% by weight of the carbon fiber (B).

Examples of the thermoplastic resin (A) can include polyphenylene sulfides, polyamides, polyalkylene terephthalates, polyacetals, polyimides, polyphenylene oxides, polysulphones, polyamideimides, polyethersulfones, liquid crystalline polymers, polyetherketones, polyetherimides, polyolefins, acrylonitrile-butadiene-styrene copolymers, polystyrenes (including syndiotactic polystyrenes), and the like, and combinations thereof. The polyalkylene terephthalate can be polyethylene terephthalate and/or polybutylene terephthalate, and the polyolefin can be polypropylene and/or polyethylene.

The carbon fiber (B) is well known to one skilled in the art and is commercially available. Polyacrylonitrile (PAN)-based and/or pitch-based carbon fibers can be used. The carbon fiber may have an average diameter of from about 5 to about 30 μm, a length of from about 8 to about 20 mm, and an aspect ratio (length/diameter: l/d) of from about 270 to about 4,000.

Examples of the nano metal particles in the fillers (C) can include silver, cobalt, iron and nickel nano metal particles.

The composite filler may comprise about 20 to about 90 parts by weight of the nano metal particles based on about 100 parts by weight of the carbon nanotubes.

The thermoplastic resin composition of the present invention may further comprise one or more additives selected from the group consisting of antimicrobial agents, release agents, thermostabilizers, antioxidants, photostabilizers, compatibilizing agents, inorganic additives, surfactants, nucleating agents, coupling agents, plasticizers, reinforcing agents, admixtures, coloring agents such as dyes and/or pigments, stabilizers, lubricant, antistatic agents, and mixtures thereof.

The EMI shielding article in accordance with the present invention is prepared from the thermoplastic resin composition.

The EMI shielding article of the present invention can have an EMI shielding effectiveness value of from about 30 to about 45 dB and a surface resistance value of from about 10⁻¹ to about 15Ω/□.

### DETAILED DESCRIPTION OF THE INVENTION

The present invention now will be described more fully hereinafter in the following detailed description of the invention in which some but not all embodiments of the invention are described. Indeed, this invention may be embodied in many different forms and should not be construed as limited to the embodiments set forth herein; rather, these embodiments are provided so that this disclosure will satisfy applicable legal requirements.

The present invention relates to a thermoplastic resin composition that can have excellent EMI shielding and/or injection molding processability.

The thermoplastic resin composition of the present invention comprises (A) a thermoplastic resin, (B) a carbon fiber, and (C) one or more fillers. The fillers can include nano metal particles surface coated with graphite crystalline nano carbon particles, composite fillers which are carbon nanotubes coated with nano metal particles, and composite fillers which are carbon nanotubes supporting nano metal particles.

The thermoplastic resin composition of the present invention may comprise about 1 to about 8 parts by weight of the fillers (C) based on about 100 parts by weight of a base resin including about 50 to about 80% by weight of the thermoplastic resin (A) and about 20 to about 50% by weight of the carbon fiber (B).

The detailed descriptions of each component of the thermoplastic resin composition of the present invention are as follows:

The types of thermoplastic resin (A) useful in the present invention are well known to those skilled in the art, and commercially available thermoplastic resins can be used without limitation.

Examples of the thermoplastic resin (A) can include without limitation polyphenylene sulfides, polyamides, polyalkylene terephthalates, polyacetals, polyimides, polyphenylene oxides, polysulphones, polyamideimides, polyethersulfones, liquid crystalline polymers, polyetherketones, polyetherimides, polyolefins, acrylonitrile-butadiene-styrene copolymers, polystyrenes (including syndiotactic polystyrenes), and the like, and combinations thereof. In exemplary embodiments, polyphenylene sulfide can be used. Examples of the polyalkylene terephthalates can include without limitation polyethylene terephthalates and/or polybutylene terephthalates, and examples of the polyolefins can include without limitation polypropylenes and/or polyethylenes.

The types of carbon fibers (B) useful in the present invention are well known to skilled in the art, and commercially carbon fibers can be used without limitation. Examples of the carbon fiber (B) can include without limitation conventional PAN-based carbon fibers, pitch-based carbon fibers, and the like, and combinations thereof.

The carbon fiber (B) may be carbon-based or graphite-based. Examples of the carbon-based carbon fibers can include without limitation carbon fibrils, carbon fibers, carbon nanotubes, and the like, and combinations thereof.

The carbon fiber may have an average diameter of about 5 to about 30 tm a length of about 8 to about 20 mm, and an aspect ratio (length/diameter: l/d) of about 270 to about 4,000. When the average diameter and the length of the carbon fiber (B) are within the aforementioned ranges, an article formed of the thermoplastic resin composition can exhibit good surface resistance. When the aspect ratio is within the aforementioned range, percolation networks can be easily formed in the thermoplastic resin composition.

The thermoplastic resin composition of the present invention comprises a base resin including about 50 to about 80% by weight of the thermoplastic resin (A) and about 20 to about 50% by weight of the carbon fiber (B).

In some embodiments, the base resin can include the thermoplastic resin (A) in an amount of about 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, or 80% by weight. Further, according to some embodiments of the present invention, the thermoplastic resin (A) may be present in an amount of from about any of the foregoing amounts to about any other of the foregoing amounts.

In some embodiments, the base resin can include the carbon fiber (B) in an amount of about 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, or 50% by weight. Further, according to some embodiments of the present invention, the carbon fiber (B) may be present in an amount of from about any of the foregoing amounts to about any other of the foregoing amounts.

If the amount of the carbon fiber (B) is less than about 20% by weight, surface resistance can increase so that electrical conductivity deteriorates. Such deterioration may significantly reduce EMI shielding properties. If the amount of the carbon fiber (B) is more than about 50% by weight, it may deteriorate injection molding processability.

Examples of the fillers (C) of the present invention can include nano metal particles surface coated with graphite crystalline nano carbon particles, composite fillers which are carbon nanotubes coated with nano metal particles, and composite fillers which are carbon nanotubes supporting nano metal particles.

The composite fillers in which nano metal particles are coated onto carbon nanotubes means that the nano metal particles are uniformly dispersed or distributed on the carbon nanotubes. The composite fillers in which nano metal particles are supported by carbon nanotubes means that the nano metal particles are not uniformly dispersed or distributed (i.e., are non-uniformly distributed) on the carbon nanotubes.

The nano metal particles used in the fillers (C) should have high electrical conductivity for good electric wave shielding, and should have good magnetic properties for good magnetic wave shielding. Examples of suitable nano metal particles can include without limitation platinum-group transition metals with high electrical conductivity such as Pd, Pt, Sn alloys thereof and the like; metals with good magnetic properties such as cobalt, iron, nickel, silver, tin, copper, and the like; and combinations thereof. In exemplary embodiments, silver, which has the highest electrical conductivity of all metals, may be used. If cobalt is used as the nano metal particles supported by the carbon nanotubes, the cobalt may not be uniformly dispersed on the carbon nanotubes due to its shape, which can deteriorate EMI shielding properties.

The diameter of the nano metal particles can be about 100 nm or less. For example, the diameter of the nano metal particles can be about 10 to about 100 nm, and as another example about 50 to about 100 nm. The use of larger diameter nano metal particles can improve EMI shielding properties exhibited by the thermoplastic resin composition of the invention.

The carbon nanotubes used in the composite filler can be bundle type and/or cotton type carbon nanotubes. Further, the carbon nanotubes used in the composite filler can be single-walled carbon nanotubes, double-walled carbon nanotubes and/or multi-walled carbon nanotubes. In exemplary embodiments, double-walled carbon nanotubes in the form of fibers can be used.

The composite filler comprises about 20 to about 90 parts by weight of nano metal particles based on about 100 parts by weight of carbon nanotubes. In some embodiments, the composite filler can include the nano metal particles in an amount of about 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, or 90 parts by weight. Further, according to some embodiments of the present invention, the nano metal particles may be present in an amount of from about any of the foregoing amounts to about any other of the foregoing amounts.

If the amount of the nano metal particles is less than about 20 parts by weight, the contact area between the particles can be reduced. If the amount of the nano metal particles is more than about 90 parts by weight, the carbon nanotubes can become tangled, which can cause a significant decrease in the aspect ratio of the composite filler.

The thermoplastic resin composition of the present invention may comprise about 1 to about 8 parts by weight of the fillers (C) based on about 100 parts by weight of a base resin comprising the thermoplastic resin (A) and the carbon fiber (B). In some embodiments, the thermoplastic resin composition can include the fillers (C) in an amount of about 1, 2, 3, 4, 5, 6, 7, or 8 parts by weight. Further, according to some embodiments of the present invention, the fillers (C) may be present in an amount of from about any of the foregoing amounts to about any other of the foregoing amounts.

If the amount of the fillers (C) is less than about 1 part by weight, the EMI shielding properties of the thermoplastic resin composition can deteriorate. If the amount of the fillers (C) is more than about 8 parts by weight, basic properties of the thermoplastic resin composition, such as injection molding processability, can deteriorate. Further, it can be difficult to mix carbon nanotubes with a thermoplastic resin due to its low bulk density.

The thermoplastic resin composition can further include one or more additives. Examples of the additives can include without limitation antimicrobial agents, release agents, thermostabilizers, antioxidants, photostabilizers, compatibilizing agents, colorants such as dyes and/or pigments, inorganic additives, surfactants, nucleating agents, coupling agents, plasticizers, reinforcing agents, admixtures, stabilizers, lubricants, antistatic agents, and the like, and mixtures. The additives can be used in conventional amounts. For example, the thermoplastic resin composition may include one or more additives in an amount of about 0.01 to about 10 parts by weight based on about 100 parts by weight of the base resin including the thermoplastic resin (A) and the carbon fiber (B).

A thermoplastic resin composition that can have excellent EMI shielding properties can be prepared using conventional methods for preparing resin compositions. For example, the thermoplastic resin (A), carbon fiber (B), fillers (C) and other optional additives of the present invention can be mixed, and then the composition can be injection and/or extrusion molded using conventional techniques to formed an EMI shielding article.

The EMI shielding article in accordance with the present invention is prepared from the aforementioned thermoplastic resin composition.

The EMI shielding article in accordance with the present invention can have an EMI shielding effectiveness value of from about 30 to about 45 dB and a surface resistance value of from about 10⁻¹ to about 15Ω/□.

The present invention will be further defined in the following examples, which are intended for the purpose of illustration and are not to be construed as in any way limiting the scope of the present invention.

### EXAMPLES

The particulars of each component used in the Examples of the present invention are as follows:

(A) Thermoplastic resin

A linear-type polyphenylene sulfide is used, and is made by Deyang Inc. (Product name: PPS-hb).

(B) Carbon fiber

A fiber-shaped multi-walled carbon nanotube is used, and is made by Nanocyl Inc. (Product name: NC 7000).

### (C) Fillers

(C1) A filler of nano nickel particles having diameters of about 50 nm surface coated with crystalline graphite nano carbon particles is used, and is made by Nano Technologies, Inc. (Product Name: Ni—C-50).

(C2) A filler of a nano nickel particles having diameters of about 40 nm surface coated with crystalline graphite nano carbon particles is used, and is made by Nano Technologies, Inc. (Product Name: Ni—C-40).

(C3) A composite filler which includes about 85 parts by weight of nano cobalt particles supported on carbon nanotubes based on about 100 parts by weight of carbon nanotubes is used, and is made by Bioneer Corporation (Product Name: CNT-Co85).

(C4) A composite filler which includes about 50 parts by weight of nano cobalt particles supported on carbon nanotubes based on about 100 parts by weight of carbon nanotubes is used, and is made by Bioneer Corporation (Product Name: CNT-Co50).

(C5) A composite filler which includes about 50 parts by weight of nano iron particles supported on carbon nanotubes based on about 100 parts by weight of carbon nanotubes is used, and is made by Bioneer Corporation (Product Name: CNT-Fe50).

(C6) A composite filler which includes about 85 parts by weight of nano silver particles supported on carbon nanotubes based on about 100 parts by weight of carbon nanotubes is used, and is made by Bioneer Corporation (Product Name: CNT-Ag85).

### Method for Testing Properties

(1) EMI shielding effectiveness (dB) is measured using a test specimen (2.1 mm thickness, 6 mm×6 mm plate) at 1 GHz in accordance with ASTM D4935-10.

(2) Surface resistance (Ω/□) is measured by 4 point probe method using a Loresta-GP meter available from Mitsubishi Chemical Corporation.

### Examples 1-8

Fillers (C) in the amounts presented in the following Table 1 are added based on 100 parts by weight of a thermoplastic resin (A) and a carbon fiber (B), and the composition is then extruded by using a twin screw extruder (L/D=35, Φ=45 mm) to be shaped into pellets. The resulting pellets are prepared at 300° C. to form test specimens to measure EMI shielding effectiveness and surface resistance.

The content ratios of (A) and (B) in the following Table 1 are represented by % by weight based on 100% by weight of (A) and (B), and the content ratio of (C) is represented by parts by weight based on 100 parts by weight of (A) and (B).

TABLE 1

| | | Examples | | | | | | | |
|---|---|---|---|---|---|---|---|---|---|
| | | 1 | 2 | 3 | 4 | 5 | 6 | 7 | 8 |
| (A) | | 70 | 70 | 70 | 70 | 70 | 70 | 70 | 70 |
| (B) | | 30 | 30 | 30 | 30 | 30 | 30 | 30 | 30 |
| (C) | (C1) | 2 | — | — | — | — | — | — | — |
| | (C2) | — | 2 | 5 | — | — | — | — | — |
| | (C3) | — | — | — | 2 | — | — | — | — |
| | (C4) | — | — | — | — | 2 | — | — | — |
| | (C5) | — | — | — | — | — | 2 | — | — |
| | (C6) | — | — | — | — | — | — | 2 | 5 |

| | | | | | | | | |
|---|---|---|---|---|---|---|---|---|
| EMI shielding | 36.9 | 34.8 | 37.8 | 37.3 | 31.8 | 34.1 | 35.9 | 39.4 |
| effectiveness | | | | | | | | |
| Surface | 6.54 | 7.53 | 5.84 | 7.32 | 11.20 | 8.83 | 6.08 | 4.00 |
| resistance | | | | | | | | |

The results presented in the above Table 1 show that Examples 1 to 8 using the fillers (C) of the present invention exhibit good EMI shielding properties and surface resistance.

Examples 1 and 2 use fillers in which a surface of nano metal particles is coated with graphite crystalline nano carbon particles. Example 1, which includes nano metal particles having large diameters, exhibits superior EMI shielding properties. Examples 2 and 3 use nano metal particles with the same diameter, and Example 3 with a high filler amount exhibits superior EMI shielding properties.

Examples 4 and 5 use composite fillers in which nano cobalt particles are supported on carbon nanotubes. Example 4 which includes supported nano cobalt particles in a high amount, exhibits good EMI shielding properties.

Examples 7 and 8 use composite fillers in which nano silver particles are supported on carbon nanotubes. Examples 7 and 8 both exhibit good EMI shielding properties due to the high electrical conductivity of silver. Example 8 which includes nano silver particles in a high amount exhibits superior EMI shielding properties.

Many modifications and other embodiments of the invention will come to mind to one skilled in the art to which this invention pertains having the benefit of the teachings presented in the foregoing descriptions. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation, the scope of the invention being defined in the claims.

That which is claimed is:

1. A thermoplastic resin composition having EMI shielding properties comprising: (A) a thermoplastic resin; (B) a carbon fiber; and (C) fillers comprising nano metal particles surface coated with graphite crystalline nano carbon particles, composite fillers which include carbon nanotubes coated with nano metal particles, composite fillers which include carbon nanotubes supporting nano metal particles, or a combination thereof.

2. The thermoplastic resin composition according to claim 1, wherein the thermoplastic resin composition comprises about 1 to about 8 parts by weight of the fillers (C) based on about 100 parts by weight of a base resin comprising about 50 to about 80% by weight of the thermoplastic resin (A) and about 20 to about 50% by weight of the carbon fiber (B).

3. The thermoplastic resin composition according to claim 1, wherein the thermoplastic resin (A) comprises polyphenylene sulfide, polyamide, polyalkylene terephthalate, polyacetal, polyimide, polyphenylene oxide, polysulphone, polyamideimide, polyethersulfone, liquid crystalline polymer, polyetherketone, polyetherimide, polyolefin, acrylonitrile-butadiene-styrene copolymer, polystyrene, or a combination thereof.

4. The thermoplastic resin composition according to claim 3, wherein the polyalkylene terephthalate comprises polyethylene terephthalate, polybutylene terephthalate, or a combination thereof and wherein the polyolefin comprises polypropylene, polyethylene, or a combination thereof.

5. The thermoplastic resin composition according to claim 1, wherein the carbon fiber (B) has an average diameter of about 5 to about 30 μm and a length of about 8 to about 20 mm.

6. The thermoplastic resin composition according to claim 1, wherein the carbon fiber (B) has an aspect ratio (length/diameter: l/d) of about 270 to about 4,000.

7. The thermoplastic resin composition according to claim 1, wherein the nano metal particles comprise silver, cobalt, iron, nickel, or a combination thereof.

8. The thermoplastic resin composition according to claim 1, wherein the composite filler comprises about 20 to about 90 parts by weight of the nano metal particles based on about 100 parts by weight of the carbon nanotubes.

9. The thermoplastic resin composition according to claim 1, further comprising an additive selected from the group consisting of antimicrobial agents release agents, thermostabilizers, antioxidants, photostabilizers, compatibilizing agents, colorants, inorganic additives, surfactants, nucleating agents, coupling agents, plasticizers, reinforcing agents, admixtures, stabilizers, lubricants, antistatic agents, and mixtures thereof.

10. An EMI shielding article prepared from the thermoplastic resin composition according to claim 1.

11. The EMI shielding article according to claim 10, wherein the article has an EMI shielding effectiveness value of about 30 to about 45 dB.

12. The EMI shielding article according to claim 10, wherein the article has a surface resistance value of 10⁻¹ to 15 Ω/□.
